(19) United States
(12) Patent Application Publication
(10) Pub. No.: US 2024/0266855 A1
(43) Pub. Date: Aug. 8, 2024

(54) CONTROL DEVICE OF A BATTERY STORE

(71) Applicant: ELRINGKLINGER AG, Dettingen/Erms (DE)

(72) Inventors: Lars WELLER, Dettingen/Erms (DE); Ulrich Benzel, Dettingen/Erms (DE)

(21) Appl. No.: 18/565,452

(22) PCT Filed: May 30, 2022
(86) PCT No.: PCT/EP2022/064627

§ 371 Date: Nov. 29, 2023

(30) Foreign Application Priority Data
May 31, 2021 (DE) 102021114071.4

(51) Int. Cl. H02J 7/00; G01R 31/382

(52) U.S. Cl. CPC H02J 7/0047; G01R 31/382; H02J 7/0013; H02J 7/00714

(57) ABSTRACT

A control device of a battery storage device, preferably a control device for and/or in a high-voltage battery storage device of an electric vehicle, wherein modules (Mod 1, . . . , Mod 16) are interconnected in the battery storage device via electromechanical components, e.g. in the form of contactors, fuses, and busbars, and are connected to a battery management system for controlling charging and discharging. In order to create a control device for a battery storage device by means of which the string currents are measured with a high degree of accuracy, it is proposed that in addition to a sensor for a total current, the control device is also connected to a sensor, which is embodied to measure a differential current between two strings.

### FIELD OF THE INVENTION

The present invention relates to a control device of a battery storage device, preferably a control device for and/or in a high-voltage battery storage device of an electric vehicle.

### BACKGROUND OF THE INVENTION

In addition to stationary applications in which they serve as emergency power supplies and buffers for power peaks, large battery storage devices are now regularly also used in purely electric and hybrid electric vehicles, i.e. as a substitute for propulsion by internal combustion engines. In addition to enclosed units in the form of battery cells and/or battery modules and elements for interconnecting these modules, these battery storage devices also contain a device for monitoring and controlling charging and discharging processes in the form of a so-called battery management system, or BMS for short. A battery management system BMS uses signals from the battery cells and battery modules to determine the battery states in a high-voltage battery, such as state of charge SOC, internal resistance Ri, and state of health SOH. The current and the reaction of a cell voltage are used to determine the internal resistance Ri of the cells. The internal resistance Ri can in turn be used to calculate the state of health SOH. The state of health SOH is mainly determined in relation to the stored capacity by a power meter during operation. For both the internal resistance Ri and the state of health SOH, it is therefore crucial to know the current that the cell is experiencing. This is also crucial with regard to both the current limiting and the permissible current at the cell level. The difficulty that this presents with multi-string systems is that the current of each string would have to be measured individually. Often only the total current is measured, in which case it is assumed that each string is experiencing the same current.

Both shunt sensors and Hall sensors, which measure the absolute current, are presently used for single-string current measurement in multi-string systems. With a large measuring range, both current sensors have a measuring tolerance in the ampere range. In multi-string systems, however, there can be deviations in the current flow of the individual strings, i.e. so-called differential currents, which cause the strings to age differently and cannot be detected with conventional methods.

The object of the present invention, therefore, is to create a control device for a battery storage device that measures string currents with a high degree of accuracy. The results are then used to accurately determine the internal resistances Ri, the SOH, and the SOC of the individual strings. This also more reliably ensures that a permissible current is not exceeded at the string level.

### SUMMARY OF THE INVENTION

According to the invention, this object is attained by a control device that is provided for controlling a battery storage device of an electric vehicle or the like, wherein, in addition to a sensor for a total current, the control device is also connected to a sensor that is embodied to measure a differential current between two strings because the additional sensor is embodied to measure a difference in a respective current flow between high-voltage connections of the two strings.

The invention is therefore essentially based on the realization that a current sensor for measuring an absolute current must have a very large measuring range, which is accompanied by an excessively high measuring tolerance. A differential current reliably indicates a potential problem, though, even if it is comparatively small. This means that a current sensor with a large measuring range does not have to be provided in the case of a differential current measurement, as a result of which a measuring tolerance of such a differential current measuring device also turns out to be significantly lower and consequently, more reliable measurement results are achieved overall.

Accordingly, in order to measure a differential current flow, a Hall sensor is provided in which the high-voltage lines of two strings are arranged extending in opposite directions through the Hall sensor and by means of currents oriented in opposite directions in the strings extending through the Hall sensor, only a difference between the flowing currents in the Hall sensor can be detected. In addition to indicating an absolute value of a difference, this type of sensor is in principle also advantageously suitable for indicating the greater of the two current flows based on the sign of a sensor output signal.

In a preferred embodiment of the invention, a measuring shunt is provided as a sensor for a total current flow. By combining differential current measurement and absolute or total current measurement, the respective string current can be calculated as accurately as possible. As a result, both the permissible absolute current and the permissible string current can be better monitored and the battery or more precisely, the cell of the modules can thus be better protected.

Preferably, a differential current can be added up over the service life of the relevant module and stored in a memory in a fail-safe way. The total current and the differential current are used to calculate the individual string currents, which are also added up and stored in a fail-safe way, particularly in an EPROM.

In one embodiment of the invention, an additional current limitation is provided at the string level. This is embodied as a safety measure so that the string currents in a two-string system are not permitted to exceed half of the maximum permissible total current.

An above-described device can generally and theoretically be expanded to multi-string systems with n strings and correspondingly n−1 Hall sensors, whereby in practice, the use with 2-string and 3-string systems is currently the most interesting.

Monitoring the individual strings is also important in order to reduce the permissible total current to the permissible string current in the event of the failure of a string, e.g. due to an internal short-circuit of a cell in a string. This ensures that the cells in the last remaining current-carrying string do not experience too high a current. This greatly reduces the otherwise potential risk, for example, of a thermal runaway effect being triggered.

### BRIEF DESCRIPTION OF THE DRAWINGS

Additional features and advantages of embodiments according to the invention will be explained in greater detail below with reference to exemplary embodiments based on the drawings. In the drawings:

FIG. 1: is a schematic circuit diagram of a battery storage device comprising a control unit and a plurality of electrical storage cells and sensors and

FIG. 2: is a schematic circuit diagram for the installation and wiring of a Hall sensor in a device according to FIG. 1.

### DETAILED DESCRIPTION OF THE INVENTION

The same reference symbols are used consistently for the same elements in the figures. Without limiting the field of application in any way, the discussion below will focus on only one use of a control device of a battery storage device according to the invention in a purely electric vehicle, which is not itself described in greater detail. It is readily apparent to the person skilled in the art, however, that devices according to the invention can be used in land vehicles, watercraft, and aircraft, but can also be used very advantageously in stationary energy storage devices, particularly in conjunction with wind power and/or photovoltaic systems.

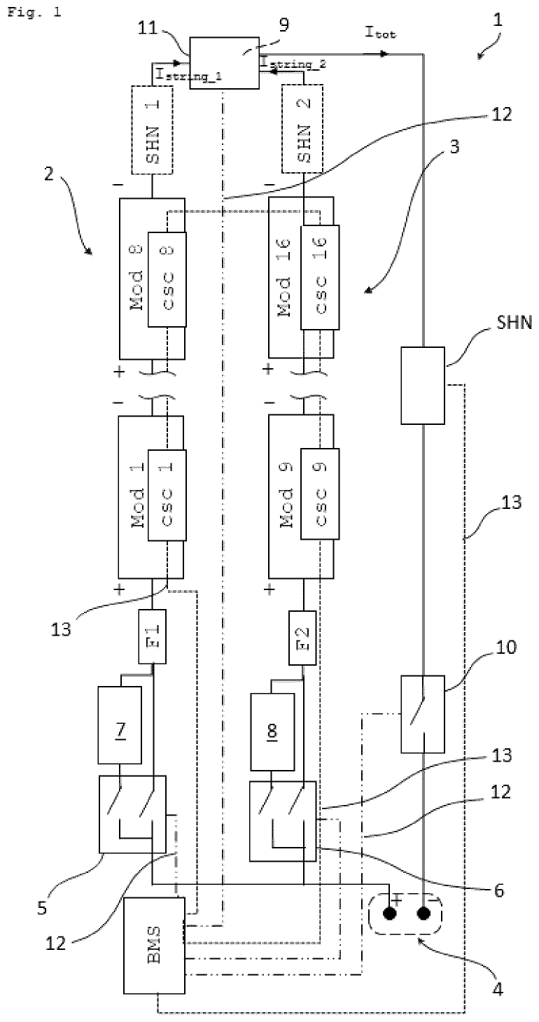

The sketch in FIG. 1 shows a circuit diagram of a battery storage device 1 with 16 modules Mod 1 to Mod 16, each of which comprises a plurality of elementary electrical storage cells that are not shown in detail. For each of these storage cells, a cell sensor circuit csc 1 . . . csc 16 is provided in the respective module for electrical and thermal monitoring.

For the sake of clarity, only the modules Mod 1, Mod 8, Mod 9, and Mod 16 are shown as an abbreviated form representing the sixteen modules mentioned above, which are connected to form two sub-strings 2, 3. The first sub-string 2 comprises a series connection of modules Mod 1 to Mod 8 and the second sub-string 3 comprises a series connection of modules Mod 9 to Mod 16. The battery storage device 1 shown is in an idle state, i.e. external electrical terminals 4 with positive and negative polarity are isolated from the modules of both sub-strings 2, 3 by means of contactors 5, 6 and precharging relays 7, 8.

The modules Mod 1, . . . , Mod 16 are interconnected to form two sub-strings 2, 3 with the same nominal voltage. The two sub-strings 2, 3 here are identically constructed as a series connection of eight modules. A voltage of 400 V is present in both sub-strings 2, 3. They are each connected at an electrically positively charged end via a fuse F1, F2 to a contactor 5, 6 and are connected to a precharging relay 7, 8. At an electrically negatively charged end, the sub-strings 2, 3 embodied as HV busbars according to the prior art are connected to a summing point 9 via current measuring resistors SHN1, SHN2. A negatively charged external terminal 4 of the battery storage device 1 is also connected to the summing point 9 via a contactor 10.

The use of current measuring resistors SHN1, SHN2 is a proven technique, but one which in addition to increased losses, provides rather inaccurate results due to a very large measuring range. According to the invention, instead of being routed via current measuring resistors SHN1, SHN2 that are only indicated with dashed lines, the sub-strings 2, 3 are therefore routed through a Hall sensor 11 with partial currents flowing in opposite directions therein in an operating state in order to determine a differential current between the partial currents flowing through each of the sub-strings 2, 3. The sign of a measurement result of the Hall sensor 11 indicates which of the partial currents is the greater one in each case. A corresponding line 12 constitutes part of an analog communication network—depicted with a dot-and-dash line in FIG. 1—of the BMS with the Hall sensor 11 and the HV contactors 5, 6. In addition to the sub-strings 2, 3 embodied as HV busbar parts and the analog communication network, a data bus 13 depicted with a dashed line is also provided as a third type of electrical connection line. This data bus 13 is embodied here as a reversible ISO SPI, i.e. as a synchronous serial data bus in which the data transmission takes place according to the master-slave principle using three lines. The slaves are always selected by a master and in this case, the communication is carried out bidirectionally and therefore in full-duplex mode.

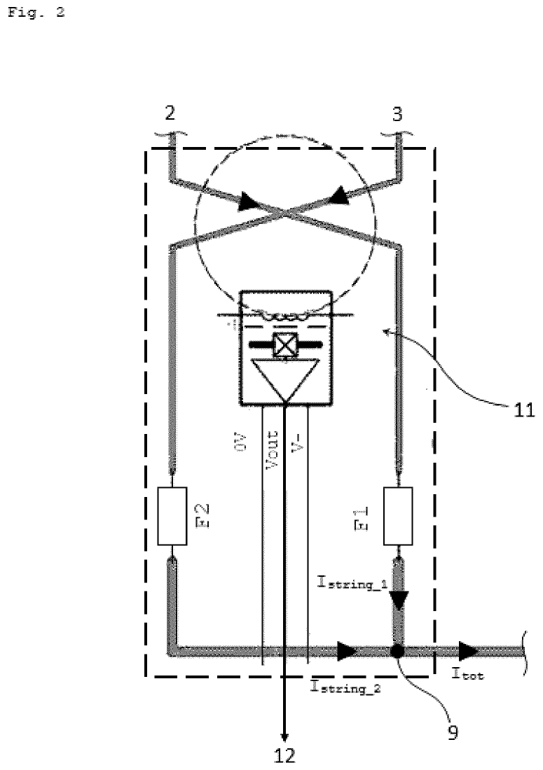

FIG. 2 shows a circuit diagram for installing the Hall sensor 11 in a device according to FIG. 1 with internal details. The sub-strings 2, 3 are routed through the Hall sensor 11 in such a way that the partial currents flow through them in opposite directions from each other when the battery storage device 1 is in operation. This means that only a difference in the current flows through the respective sub-strings 2, 3 can be electromagnetically measured in the Hall sensor 11.

A measurement of differential currents in a multi-string battery of the type shown here as an example can be carried out with a high degree of accuracy due to the comparatively small measuring range. For this purpose, the Hall sensor 11 is connected to an analog input of the BMS via the line 12. The power supply of the Hall sensor 11 is ensured, for example, with a supply voltage of 5 V+/−0.25 V and a maximum current consumption of 20 mA via an analog output of the BMS. This functionality for the use of the Hall sensor 11 can be activated via a parameter in the configuration of the BMS.

A current measurement for the entire system composed of the strings 2, 3 continues to run via a shunt, in this case SHN. The total current and differential current are used to calculate the individual string currents of strings 2, 3. An additional current limitation has been introduced at the string level. This is set up so that the string currents I_{string_1}, I_{string_2} in the present case of only two strings 2, 3 are not permitted to exceed half the maximum permissible total current, i.e. I_{max_string}=1/2 I_{max_tot}.

The differential current of the two strings 2, 3 is added up over the total service life and stored in an EEPROM, which is part of the BMS in this exemplary embodiment without being graphically depicted in greater detail. The respective internal resistance Ri for each string 2, 3 is also calculated. Based on this, a separate state of health SOH is calculated for each string.

The differential current measurement with a Hall sensor offers the possibility, with only a slight modification to the hardware, of monitoring equalizing currents in a multi-string battery over its service life with increased measurement accuracy since only a comparatively small measurement range is required. This increases the accuracy in determining the internal resistance Ri, the state of health SOH, and the state of charge SOC since this method determines a respective current more accurately at the string level. The maximum permissible current flow at the string level can therefore also be monitored and if necessary, limited in order to increase the overall operational reliability of this HV battery storage device. The aging behavior of the battery can thus be better monitored and the essential battery states can be determined more accurately in the BMS.

1. A control device of a battery storage device, comprising a plurality of modules interconnected in the battery storage device via electromechanical components, and the plurality of modules are connected to a battery management system for controlling charging and discharging, wherein, in addition to a sensor for a total current, the control device is also connected to a sensor, which is embodied to measure a differential current between two strings.

2. The control device according to claim 1, further comprising a Hall sensor for measuring a difference in a current flow of the two strings, wherein high-voltage lines of the two strings are arranged extending in opposite directions and the high-voltage lines have partial currents flowing through the high-voltage lines in opposite directions.

3. The control device according to claim 1, wherein a measuring shunt is provided as a sensor for a total current flow.

4. The control device according to claim 1, wherein a differential current is added up over a service life of a relevant one of the plurality of modules and the differential current is storable in a memory in a fail-safe way.

5. The control device according to claim 3, further comprising an additional current limitation at a level of the two strings.

6. The control device according to claim 1, wherein the device is expandable to use with multi-string systems with n strings and n−1 Hall sensors.

7. The control device according to claim 1, wherein the control device is arranged in the battery management system and is embodied to automatically store, in a fail-safe way, a difference in the current flow of the two strings added up over a service life of a relevant one of the plurality of modules.

8. The control device according to claim 1, wherein the battery storage device is a battery storage device of an electric vehicle.

9. The control device according to claim 1, wherein the electromechanical components comprise at least one of the group consisting of contactors, fuses, and busbars.
